(19) United States
(12) Patent Application Publication
(10) Pub. No.: US 2024/0203767 A1
(43) Pub. Date: Jun. 20, 2024

(54) VIBRATION SENSOR ASSEMBLY

(71) Applicant: APPLIED MATERIALS, INC., Santa Clara, CA (US)

(72) Inventor: Venkata Raghavaiah Chowdhary Kode, Pflugerville, TX (US)

(21) Appl. No.: 18/081,897

(22) Filed: Dec. 15, 2022

(51) Int. Cl. H01L 21/67; B25J 11/00; B25J 19/02; G01P 1/00; G01P 15/00; G06F 3/14; G08B 21/18

(52) U.S. Cl. CPC H01L 21/67276; B25J 11/0095; B25J 19/02; G01P 1/00; G01P 15/00; G06F 3/14; G08B 21/182

(57) ABSTRACT

A system includes a controller, a substrate transfer device including one or more moveable members, and a vibration sensor assembly coupled to a member of the one or more moveable members. The vibration sensor assembly includes an accelerometer configured to detect vibration of the substrate transfer device and a processing device coupled to the accelerometer. The processing device is to receive vibration data from the accelerometer. The processing device is further to determine a vibration frequency peak of the vibration data. The vibration frequency peak corresponds to a critical frequency associated with the substrate transfer device. The processing device is further to determine that the vibration frequency peak exceeds a threshold magnitude, responsive to which the processing device is further to cause a data signal indicative of the vibration frequency peak to be transmitted to the controller.

### TECHNICAL FIELD

Embodiments of the present disclosure generally relate to a vibration sensor assembly, and more specifically relate to systems, methods, and devices for determining vibration of substrate transfer devices.

### BACKGROUND

Substrate transfer devices used in substrate processing have components that wear out with use over time. Wear of such components causes vibration. As vibration increases, failure of the substrate transfer device can be predicted.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

Some of the embodiments described herein cover a system that includes a controller, a substrate transfer device having one or more moveable members, and a vibration sensor assembly coupled to a first member of the one or more moveable members. The vibration sensor assembly includes an accelerometer configured to detect vibration of the substrate transfer device. The vibration sensor assembly further includes a processing device communicatively coupled to the accelerometer. The processing device is to receive vibration data from the accelerometer. The vibration data is indicative of the vibration of the substrate transfer device. The processing device is further to determine at least one vibration frequency peak of the vibration data. The at least one vibration frequency peak corresponds to at least one critical frequency associated with the substrate transfer device. The processing device is further to determine that the at least on vibration frequency peak exceeds a threshold magnitude. Responsive to determining that the vibration frequency peak exceeds the threshold magnitude, the processing device is further to cause a data signal indicative of the at least one vibration frequency peak to be transmitted to the controller.

Additional or related embodiments described herein cover a vibration sensor assembly configured to couple to a moveable member of a substrate transfer device. The vibration sensor assembly includes an accelerometer configured to detect vibration of the substrate transfer device. The vibration sensor assembly further includes a processing device communicatively coupled to the accelerometer. The processing device is to receive vibration data from the accelerometer. The vibration data is indicative of the vibration of the substrate transfer device. The processing device is further to determine at least one vibration frequency peak of the vibration data. The at least one vibration frequency peak corresponds to at least one critical frequency associated with the substrate transfer device. The processing device is further to determine that the at least one vibration frequency peak exceeds a threshold magnitude. Responsive to determining that the vibration frequency peak exceeds the threshold magnitude, the processing device is to cause a data signal indicative of the at least one vibration frequency peak to be transmitted to a controller of the substrate transfer device.

In further embodiments, a method includes receiving vibration data from an accelerometer. The vibration data is indicative of vibration of a substrate transfer device. The method further includes determining at least one vibration frequency peak of the vibration data. The at least one vibration frequency peak corresponds to at least one critical frequency associated with the substrate transfer device. The method further includes determining that the at least one vibration frequency peak exceeds a threshold magnitude. Responsive to determining that the vibration frequency peak exceeds the threshold magnitude, the method includes causing a digital signal indicative of the at least one vibration frequency peak to be transmitted to a controller of the substrate transfer device.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a top schematic view of an example manufacturing system, according to aspects of the present disclosure.

FIG. 2 illustrates simplified block diagram of a vibration sensor assembly, according to aspects of the present disclosure.

FIG. 3 depicts an illustrative computer system architecture, according to aspects of the present disclosure.

FIG. 4 is a flow chart of a method for determining vibration in a substrate transfer device, according to aspects of the present disclosure.

FIG. 5 is a graphical representation of frequency domain vibration data associated with vibration in a substrate transfer device, according to aspects of the present disclosure.

FIG. 6 is a flow chart of a method for determining vibration in a substrate transfer device, according to aspects of the present disclosure.

FIG. 7 depicts a diagrammatic representation of a machine in the example form of a computing device within which a set of instructions, for causing the machine to perform any one or more of the methodologies discussed herein, can be executed.

### DETAILED DESCRIPTION OF EMBODIMENTS

Embodiments of the present disclosure are directed to a vibration sensor assembly. A substrate transfer device includes moveable members to transfer a substrate. For example, a substrate-handling robot can include one or more robot arms and an end effector. A substrate can be moved on the end effector from a first station to a second station responsive to the movement of the robot arms. In a similar example, a substrate transfer stage can include a moveable stage to transfer a substrate on the stage from a first station to a second station. To increase throughput of the manufacturing system, substrate transfer devices commonly undergo quick accelerations and decelerations as well as high velocities to quickly transfer substrates. The quick accelerations and decelerations may induce shock and/or fatigue in the moving parts (e.g., joints, bearings, etc.) of the substrate transfer device. With use over time, the mechanical components of the substrate transfer device are subjected to high cyclic stresses. These high cyclic stresses may induce component fatigue, shortening the life of individual components of the substrate transfer device. With continued use under such conditions, the substrate transfer device can eventually fail, necessitating the processing of substrates be paused to repair and/or replace the substrate transfer device. Such down time can be costly, especially if unscheduled.

Often, observed vibration can be indicative of the health of the mechanical components of the substrate transfer device. As the components wear, vibration may increase. For example, in a bearing between an upper arm and a forearm of a substrate-handling robot, observable vibration often increases as the bearing nears the end of its usable life. The increased vibration can further contribute to wear of the bearing. Vibration may increase until the mechanical component ultimately fails, causing the substrate transfer device to fail. Monitoring the vibration of the mechanical components can thus provide indications of the time of substrate transfer device failure.

Conventionally, prediction of premature failure of mechanical components of a substrate transfer device is accomplished by periodically taking vibration measurements of the substrate transfer device, such as during scheduled maintenance. The vibration data collected during maintenance can be used to determine whether maintenance should be performed on the substrate transfer device. However, predicting mechanical failure of the substrate transfer device can be difficult without continuous monitoring. Additionally, analyzing vibration is a time-consuming process and can lead to much longer maintenance shutdowns. Another conventional solution is to permanently install an accelerometer to monitor vibration in a critical joint of the substrate transfer device. A permanent accelerometer adds significant cost to the substrate transfer device. Additionally, conventional permanent accelerometers are tested to validate noise that can be caused by the flexing of sensor cables. Further, substrate transfer devices utilizing a permanent accelerometer are engineered to accept and operate with the conventional permanent accelerometer.

Aspects and implementations of the instant disclosure address the above-described and other shortcoming of conventional systems by providing a system (e.g., a vibration sensor assembly) to measure and transmit vibration data. In some embodiments, a system includes a substrate transfer device such as a substrate-handling robot or a substrate transfer stage. The substrate transfer device includes one or more moveable members to transfer the substrate from a first station to a second station. The controller may be configured to control the substrate transfer device and/or output indications (e.g., via a graphical user interface) of the health of the substrate transfer device. In some embodiments, the system further includes a vibration sensor assembly coupled to a member of the one or more moveable members of the substrate transfer device. In some examples, the vibration sensor assembly is coupled to a wrist member of a substrate-handling robot. The vibration sensor assembly may transmit vibration data to the controller.

In some embodiments, the vibration sensor device includes an accelerometer and a processing device communicatively coupled to the accelerometer. The accelerometer may be configured to detect vibration of the substrate transfer device, in some embodiments. The processing device may be configured to receive and process vibration data collected by the accelerometer. Additionally, the processing device may be configured to cause transmission of data indicative of the vibration of the substrate transfer device. In some embodiments, the processing device receives vibration data indicative of vibration of the substrate transfer device from the accelerometer. Similarly, the vibration data may be indicative of the health of one or more mechanical components of the substrate transfer device.

In some embodiments, the processing device determines at least one vibration frequency peak of the vibration data. To determine the at least one vibration frequency peak, the processing device may perform data processing that includes a mathematical transform operation to transform the vibration data from the time domain to the frequency domain. In some examples, in the frequency domain of the vibration data, the processing device may determine multiple frequency peaks. The frequency peaks may correspond to vibration magnitudes at frequencies such as natural vibrational frequencies and/or vibrational harmonics of the substrate transfer device. Further, the frequency peaks may indicate certain vibrational frequencies having larger amplitudes when compared to other frequencies. The frequency peaks may correspond to critical frequencies (e.g., frequencies of interest) associated with the substrate transfer device.

In some embodiments, by analyzing the frequency domain vibration data, the processing device determines that at least one vibration frequency peak exceeds a threshold magnitude. The threshold magnitude can be a first magnitude or a larger second magnitude. In some examples, the first magnitude corresponds to a warning level of vibration in the substrate transfer device. The warning level may indicate that the substrate transfer device is to be monitored more closely and/or more often. In some examples, the second magnitude corresponds to a critical level of vibration magnitude in the substrate transfer device. The critical level may indicate that mechanical failure of the substrate transfer device is imminent. In some embodiments, responsive to determining that the at least one vibration frequency peak exceeds the threshold magnitude, the processing device may cause a data signal indicative of the at least one vibration frequency peak to be transmitted to the controller. For example, the processing device may cause a warning signal to be transmitted to the controller by wireless (e.g., via Bluetooth, Wi-Fi, and/or optical transmission) indicative of a warning or critical vibration condition as indicated by the vibration frequency peak exceeding the threshold.

Embodiments of the present disclosure provide advantages over conventional systems described above. Particularly, some embodiments described herein can detect vibration in a substrate transfer device and wirelessly send a signal indicative of such to a controller. By performing the data processing internal to the vibration sensor assembly, bandwidth in the controller is freed for performing other tasks. Thus, computing resources are conserved. Additionally, embodiments described herein can allow for more accurate sensing of vibration data by eliminating wires associated with conventional vibration sensors. This can lead to more accurately predicting mechanical failure of a substrate transfer device when compared to conventional vibration sensor systems. Further, the embodiments described herein provide for continuous vibration monitoring which some conventional systems and methods do not allow. This again increases the accuracy of mechanical failure predictions. By more accurately predicting mechanical failures of substrate transfer devices, unscheduled down time for maintenance can be avoided, thus reducing cost and increasing overall substrate manufacturing system throughput.

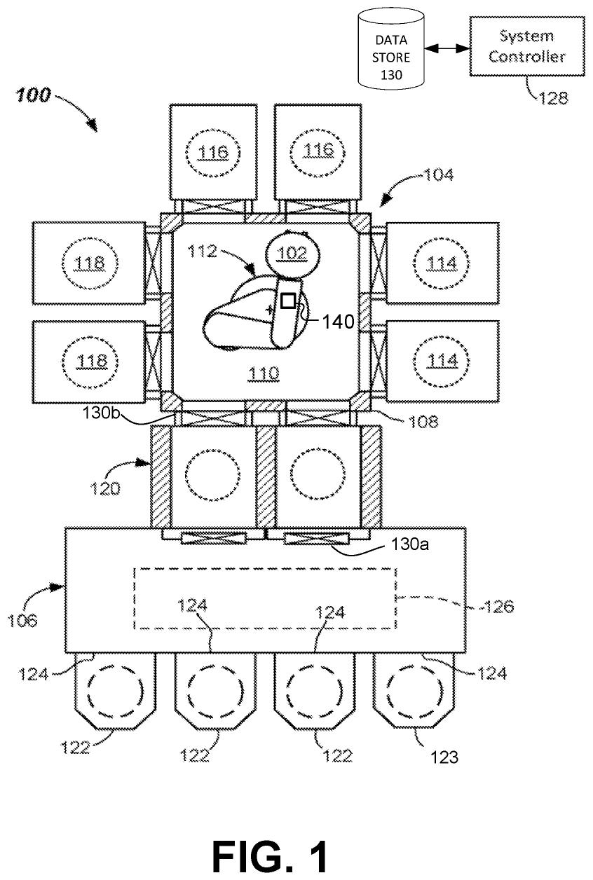

FIG. 1 is a top schematic view of an example manufacturing system 100, according to aspects of the present disclosure. Manufacturing system 100 can perform one or more processes on a substrate 102. Substrate 102 can be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 100 can include a process tool 104 and a factory interface 106 coupled to process tool 104. Process tool 104 can include a housing 108 having a transfer chamber 110 therein. Transfer chamber 110 can include one or more process chambers (also referred to as processing chambers) 114, 116, 118 disposed therearound and coupled thereto. Process chambers 114, 116, 118 can be coupled to transfer chamber 110 through respective ports, such as slit valves or the like.

Process chambers 114, 116, 118 can be adapted to carry out any number of processes on substrates 102. A same or different substrate process can take place in each process chamber 114, 116, 118. A substrate process can include atomic layer deposition (ALD), physical vapor deposition (PVD), chemical vapor deposition (CVD), etching, annealing, curing, pre-cleaning, metal or metal oxide removal, or the like. In one example, a PVD process can be performed in one or both of process chambers 114, an etching process can be performed in one or both of process chambers 116, and an annealing process can be performed in one or both of process chambers 118. Other processes can be carried out on substrates 102 therein. Process chambers 114, 116, 118 can each include a substrate support assembly. The substrate support assembly can be configured to hold substrate 102 in place while a substrate process is performed.

In some embodiments, a process chamber 114, 116, 118 can include a carousel (also referred to as a susceptor). The carousel can be disposed in an interior volume of the process chamber 114, 116, 118 and can be configured to rotate about an axial center at the process chamber 114, 116, 118 during a process (e.g., a deposition process) to ensure process gases are evenly distributed. In some embodiments, the carousel can include one or more end effectors configured to handle one or more objects. For example, the end effectors can be configured to hold a substrate, a process kit, and/or a process kit carrier. One or more sensors can be disposed at the process chamber 114, 116, 118 and can be configured to detect a placement of an object on an end effector of the carousel, in accordance with embodiments described herein.

Transfer chamber 110 can also include a transfer chamber robot 112. Transfer chamber robot 112 can include one or multiple arms where each arm includes one or more end effectors at the end of each arm. The end effector can be configured to handle particular objects, such as substrates. Alternatively, or additionally, the end effector can be configured to handle process kits (i.e., using a process kit carrier). In some embodiments, transfer chamber robot 112 can be a selective compliance assembly robot arm (SCARA) robot, such as a 2 link SCARA robot, a 3 link SCARA robot, a 4 link SCARA robot, and so on.

A vibration sensor assembly 140 may be coupled to an arm of the transfer chamber robot 112. In some embodiments, the vibration sensor assembly 140 is coupled to a wrist member of the transfer chamber robot 112. The vibration sensor assembly 140 may be configured to detect vibration of the transfer chamber robot 112. For example, vibration of an upper arm of the transfer chamber robot 112 may transmit from the upper arm, through a forearm, to the wrist member, where the vibration sensor assembly 140 may detect the vibration. Similarly, vibration of the end effector may transmit to the wrist member, where the vibration is detectable by the vibration sensor assembly. In some examples, the vibration sensor assembly 140 includes an accelerometer to detect vibration. The vibration sensor assembly 140 may include a power source, such as a battery, and/or a capacitor to power the assembly. Vibration data may be processed by a processing device of the vibration sensor assembly 140 to determine whether vibration of the transfer chamber robot 112 is within a safe and/or tolerable range. In some embodiments, the processing device of the vibration sensor assembly 140 determines whether the magnitude of a vibration frequency peak exceeds a warning threshold and/or a critical threshold.

A data signal indicative of a warning state and/or a critical state corresponding to the vibration may be sent from the vibration sensor assembly 140 to the system controller 128. The system controller 128 may prepare a notification for viewing (e.g., by a user) on a graphical user interface (GUI) indicative of the vibration. In some embodiments, the notification indicates that the vibration frequency peak exceeds a threshold magnitude and/or indicates that a preventive maintenance operation should be performed. The preventive maintenance operation of the transfer chamber robot 112 may correspond to a critical frequency of the transfer chamber robot 112 (e.g., a particular worn bearing or joint that induces vibration at the critical frequency should be lubricated and/or replaced, etc.). The vibration may be indicative of mechanical wear and/or imminent mechanical failure of one or more components of the transfer chamber robot 112.

In some embodiments, the vibration sensor assembly 140 transmits the data signal to the controller 128 wirelessly (e.g., via Wifi, Bluetooth, optical transmission, etc.). Because wireless signals may not travel through the walls of the transfer chamber 110 (e.g., the walls are metal, etc.), in some embodiments, a transmitter of the vibration sensor assembly 140 transmits the data signal when transfer ports (e.g., vacuum ports 130a and/or 130b) are open. The wireless signal can be transmitted out of the transfer chamber 110 via the open transfer ports. In some examples, the transmitter may time data transmission with the opening of the transfer ports. In some embodiments, the data signal may be optically transmitted through a transmission window of the process tool 104. In some examples, the transmitter may optically transmit the data signal to an optical receiver coupled to the system controller 128 via a transmission window in a sidewall, a bottom, and/or a top of the transfer chamber 110.

In some embodiments, the vibration sensor assembly 140 includes a power source such as a battery, and/or a capacitor configured to electrically power the vibration sensor assembly. In some embodiments, the battery and/or capacitor is rechargeable and/or replaceable. For example, a battery of the vibration sensor assembly 140 can be replaced during scheduled maintenance. In some embodiments, the power source can be inductively recharged. In some examples, an inductive charging coil in the vibration sensor assembly 140 receives electrical charge from another inductive charging coil mounted to the process tool 104. The inductive charging coil may be mounted proximate a path of the transfer chamber robot end effector, such as near a transfer port (e.g., a vacuum port). The inductive charging coil of the vibration sensor assembly 140 may receive charge from the inductive charging coil mounted to the process tool 104 when in proximity to the inductive charging coil mounted to the process tool 104 (e.g., such as when the transfer chamber robot 112 retrieves and/or places a substrate through a vacuum port, etc.). Similarly, the data signal transmitted by the vibration sensor assembly 140 may be transmitted when the transfer chamber robot 112 moves the arm to which the vibration sensor assembly 140 is coupled proximate a receiver.

A load lock 120 can also be coupled to housing 108 and substrate transfer chamber 110. Load lock 120 can be configured to interface with, and be coupled to, transfer chamber 110 on one side and factory interface 106. Load lock 120 can have an environmentally-controlled atmosphere that can be changed from a vacuum environment (wherein substrates can be transferred to and from transfer chamber 110) to an at or near atmospheric-pressure inert-gas environment (wherein substrates can be transferred to and from factory interface 106) in some embodiments. In some embodiments, load lock 120 can be a stacked load lock having a pair of upper interior chambers and a pair of lower interior chambers that are located at different vertical levels (e.g., one above another). In some embodiments, the pair of upper interior chambers can be configured to receive processed substrates from transfer chamber 110 for removal from process tool 104, while the pair of lower interior chambers can be configured to receive substrates from factory interface 106 for processing in process tool 104. In some embodiments, load lock 120 can be configured to perform a substrate process (e.g., an etch or a pre-clean) on one or more substrates 102 received therein.

Factory interface 106 can be any suitable enclosure, such as, e.g., an Equipment Front End Module (EFEM). Factory interface 106 can be configured to receive substrates 102 from substrate carriers 122 (e.g., Front Opening Unified Pods (FOUPs)) docked at various load ports 124 of factory interface 106. A factory interface robot 126 (shown dotted) can be configured to transfer substrates 102 between substrate carriers 122 (also referred to as containers) and load lock 120. In other and/or similar embodiments, factory interface 106 can be configured to receive replacement parts (e.g., process kits) from replacement parts storage containers 123. Factory interface robot 126 can include one or more robot arms and can be or include a SCARA robot. In some embodiments, a vibration sensor assembly may be coupled to one of the one or more robot arms of the factory interface robot 126. In some embodiments, factory interface robot 126 can have more links and/or more degrees of freedom than transfer chamber robot 112. Factory interface robot 126 can include an end effector on an end of each robot arm. The end effector can be configured to pick up and handle specific objects, such as substrates or process kits. Alternatively, or additionally, the end effector can be configured to handle objects such as process kits (e.g., using process kit carriers).

Any conventional robot type can be used for factory interface robot 126. Transfers can be carried out in any order or direction. Factory interface 106 can be maintained in, e.g., a slightly positive-pressure non-reactive gas environment (using, e.g., nitrogen as the non-reactive gas) in some embodiments.

In some embodiments, transfer chamber 110, process chambers 114, 116, and 118, and load lock 120 can be maintained at a vacuum level. Manufacturing system 100 can include one or more vacuum ports that are coupled to one or more stations of manufacturing system 100. For example, first vacuum ports 130a can couple factory interface 106 to load locks 120. Second vacuum ports 130b can be coupled to load locks 120 and disposed between load locks 120 and transfer chamber 110.

In some embodiments, one or more sensors can be included at one or more stations of manufacturing system 100. For example, one or more sensors can be included in transfer chamber 110 at or near a port (i.e., an entrance) of process chambers 114, 116, 118. An end effector of a robot arm (e.g., of transfer chamber robot 112) can move a substrate 102 or a process kit (i.e. using a process kit carrier) past the one or more sensors when moving the substrate 102 and/or process kit into or out of a process chamber 114, 116, 118. Each sensor can be configured to detect the substrate 102 or the process kit and/or carrier as the end effector moves the substrate 102 or the process kit and/or carrier into or out of the process chamber 114, 116, 118.

Manufacturing system 100 can also include a system controller 128. System controller 128 can be and/or include a computing device such as a personal computer, a server computer, a programmable logic controller (PLC), a microcontroller, and so on. System controller 128 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 128 can include a data storage device (e.g., one or more disk drives and/or solid state drives), a main memory, a static memory, a network interface, and/or other components. System controller 128 can execute instructions to perform any one or more of the methodologies and/or embodiments described herein. The instructions can be stored on a computer readable storage medium, which can include the main memory, static memory, secondary storage and/or processing device (during execution of the instructions).

In some embodiments, the system controller 128 is configured to receive the data signal from the vibration sensor assembly 140. The system controller 128 may perform a corrective action based on the data signal. In some embodiments, based on the data signal, the system controller 128 may prepare for display on a GUI a notification of a vibration frequency peak exceeding a threshold vibration condition (e.g., as described herein above). For example, the notification may indicate that the vibration of the substrate transfer device exceeds a warning magnitude and/or exceeds a critical magnitude. Similarly, in some embodiments, based on the data signal, the system controller 128 may prepare for display on a GUI a notification of a preventive maintenance operation of the substrate transfer device corresponding to the frequency of the vibration frequency peak. For example, the notification may indicate that a maintenance operation is to be performed on the substrate transfer device (e.g., such as lubrication or replacement of a bearing, etc.).

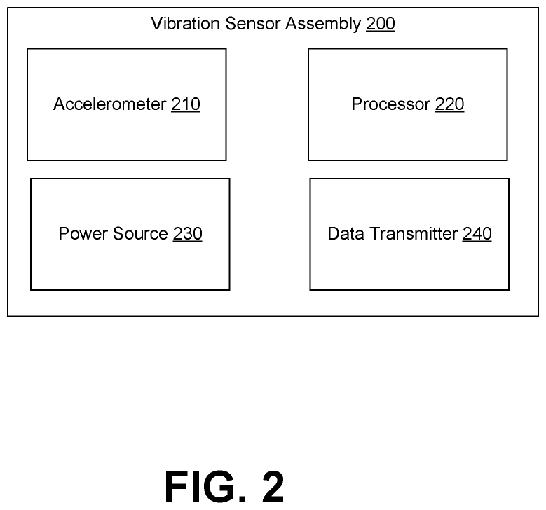

FIG. 2 illustrates simplified block diagram of a vibration sensor assembly 200, according to aspects of the present disclosure. In some embodiments, vibration sensor assembly 200 includes an accelerometer 210, a processor 220, a power source 230, and/or a data transmitter 240. The vibration sensor assembly 200 may be configured to couple to a moveable member (e.g., a robot arm, a moveable stage, etc.) of a substrate transfer device. For example, the vibration sensor assembly 200 may be configured to couple to a wrist member of a substrate-handling robot.

The accelerometer 210 may be configured to detect vibration movement. The vibration movement may be vibration in any direction (e.g., in an X direction, a Y direction, and/or a Z direction). In some embodiments, the accelerometer 210 is a vibration sensor configured to output vibration data. The accelerometer 210 may be a microelectromechanical systems (MEMS)-based sensor in some embodiments.

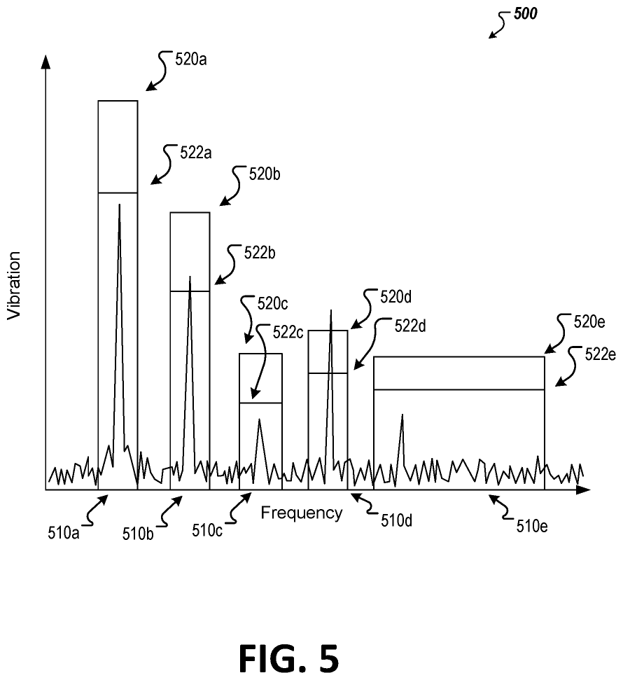

Vibration sensor data collected by the accelerometer 210 may be provided to the processor 220. In some embodiments, the processor 220 performs data processing on the raw vibration sensor data received from the accelerometer 210. In some examples, the processor 220 performs filtering of the vibration data to remove noise, converts the vibration data from analog to digital, and/or performs a transform operation such as a Fourier transform or a Fast Fourier transform to convert the vibration data from time domain to frequency domain. Based on the frequency domain vibration data, the processor 220 may determine that a frequency peak exceeds a predetermined magnitude threshold. In some examples, the processor 220 can determine that vibration at the natural frequency or at a harmonic frequency (e.g., of the substrate transfer device) exceeds a warning threshold. In similar examples, the processor 220 can determine that vibration at the natural frequency the harmonic frequency exceeds a critical threshold. In some embodiments, the processor 220 is configured (e.g., by a user) to monitor frequencies associated with the particular type of substrate transfer device to which it is coupled (e.g., or to be coupled). In some embodiments, the processor 220 is configured to identify frequency peaks at and/or near discrete vibration frequencies characteristic of the substrate transfer device. For example, the processor 22 may be configured to monitor and/or detect peak frequencies at the natural frequency of the associated substrate transfer device, at one or more harmonic frequencies, and/or at a wideband frequency (see associated description of FIG. 5 below).

In some embodiments, responsive to determining that a frequency peak exceeds a predetermined threshold, the processor 220 may cause the data transmitter 240 to transmit a data signal to a controller (e.g., of the substrate manufacturing system). The data signal may be indicative of the vibration frequency peak in some embodiments. In some examples, the data signal includes data indicating that the vibration frequency peak exceeds the warning threshold and/or the critical threshold as explained herein above. The data signal may indicate to the controller that preventive maintenance is to be completed on the substrate transfer device (e.g., that one or more mechanical components such as bearings are to be replaced on the substrate transfer device). In some embodiments, the data signal may include data indicating that a segment of a usable lifetime of a component of the substrate transfer device has expired. For example, responsive to the vibration frequency peak exceeding the warning threshold, the data signal may indicate that an early life segment of the substrate transfer device component has expired and/or that the substrate transfer device is in a mid-life state. In another example, responsive to the vibration frequency peak exceed the critical threshold, the data signal may indicate that the mid-life segment of the substrate transfer device component has expired and/or that the substrate transfer device is nearing an end-of-life.

The data signal may be transmitted by the data transmitter 240 to the controller wirelessly. For example, the data transmitter 240 may transmit the data signal by Wi-Fi or Bluetooth. In some embodiments, the data transmitter 240 may optically transmit the data signal. For example, the data transmitter 240 may include an optical emitter to optically emit a data signal to an optical receiver communicatively coupled to the controller.

The vibration sensor assembly 200 may be electrically powered by a power source 230. In some embodiments, the power source 230 includes a power storage device such as a battery and/or a capacitor. In some embodiments, the power source 230 includes circuitry to provide a constant voltage from the power storage device to the accelerometer 210, the processor 220, and/or the data transmitter 240. For example, the power source 230 may include a voltage regulator to regulate the voltage supplied from the power storage device. In some embodiments, as described herein above, the power source may be charged wirelessly (e.g., via inductive charging). In some embodiments, the power storage device of the power source 230 may be changed (e.g., during maintenance operations). For example, a battery of the power source 230 may be changed (e.g., by a user, a technician, an engineer, etc.) during routine maintenance of the substrate manufacturing system.

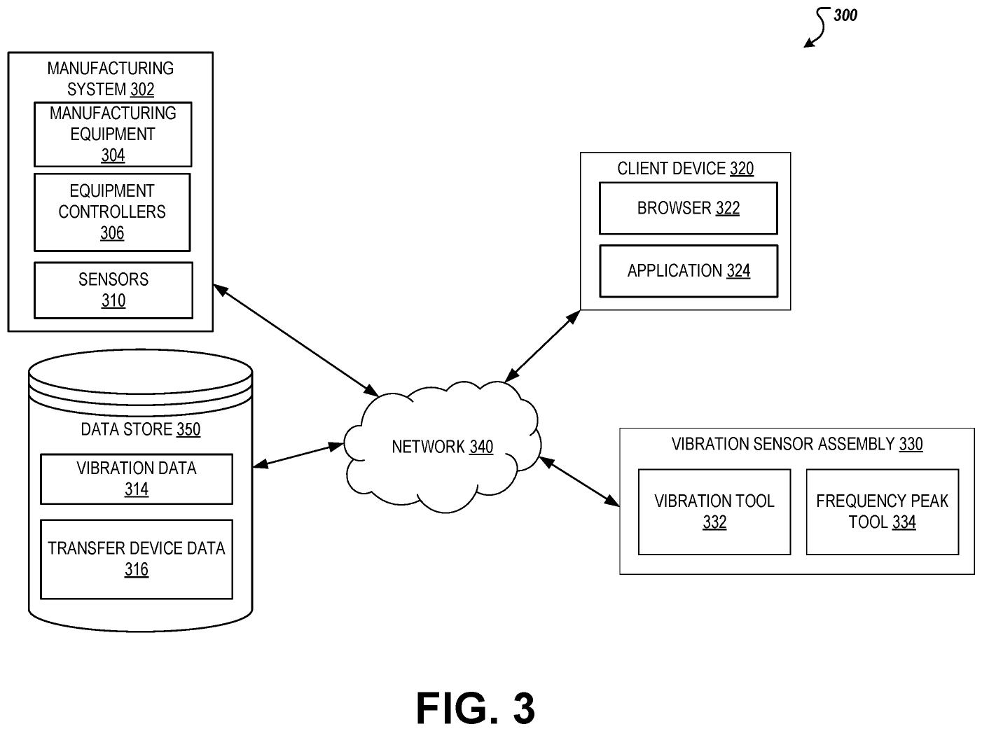

FIG. 3 depicts an illustrative computer system architecture 300, according to aspects of the present disclosure. Computer system architecture 300 includes a client device 320, manufacturing system 302, vibration sensor assembly 330, and a data store 350. The manufacturing system 302, the data store 350, and the client device 320 can each be hosted by one or more computing devices including server computers, desktop computers, laptop computers, tablet computers, notebook computers, personal digital assistants (PDAs), mobile communication devices, cell phones, hand-held computers, augmented reality (AR) displays and/or headsets, virtual reality (VR) displays and/or headsets, mixed reality (MR) displays and/or headsets, or similar computing devices. The server, as used herein, may refer to a server but may also include an edge computing device, an on premise server, a cloud, and the like.

Components of the client device 320, manufacturing system 302, vibration sensor assembly 330, and/or data store 350 can be coupled to each other via a network 340. In some embodiments, network 340 is a public network that provides client device 320 with access to manufacturing system 302, vibration sensor assembly 330, data store 350, and other publicly available computing devices. In some embodiments, network 340 is a private network that provides client device 320 access to manufacturing system 302, vibration sensor assembly 330, data store 350, and/or other privately available computing devices. Network 340 can include one or more wide area networks (WANs), local area networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

The client device 320 may be or include any personal computers (PCs), laptops, mobile phones, tablet computers, netbook computers, network connected televisions (“smart TV”), network-connected media players (e.g., Blue-ray player), a set-top-box, over-the-top (OOT) streaming devices, operator boxes, etc. The client device 320 may include a browser 322, an application 354, and/or other tools as described and performed by other systems of the system architecture 300. In some embodiments, the client device 320 may be capable of accessing the manufacturing system 302, the data store 350, and/or the vibration sensor assembly 330 and communicating (e.g., transmitting and/or receiving) data associated with vibration of a substrate transfer device included in the manufacturing system 302.

As shown in FIG. 3, manufacturing system 302 includes manufacturing equipment 304, system controllers 306, process recipes 308, and sensors 310. The manufacturing equipment 304 may be any combination of an ion implanter, an etch reactor (e.g., a processing chamber), a photolithography devices, a deposition device (e.g., for performing chemical vapor deposition (CVD), physical vapor deposition (PVD), ion-assisted deposition (IAD), and so on), or any other combination of manufacturing devices. Manufacturing equipment 304 may further include substrate transfer devices such as substrate-handling robots and/or substrate transfer stages.

The vibration sensor assembly 330 may include a vibration tool 332 and/or a frequency peak tool 334. In some embodiments, the vibration tool 332 determines vibration data 314 based on output from an accelerometer mounted to a substrate transfer device. The vibration tool 332 may perform data processing on raw sensor data received from the accelerometer. The data processing may include filtering and/or transforming the data by a mathematical transformation operation (e.g., Fourier transform, fast Fourier transform, etc.). In some embodiments, the vibration tool 332 may transform the vibration data 314 from time domain to frequency domain. The frequency peak tool 334 may determine one or more frequency peaks in the frequency domain vibration data. In some examples, the frequency peak tool 334 analyzes the frequency domain vibration data based on transfer device data 316 that reflects characteristics of the substrate transfer device. For example, the transfer device data 316 may indicate a natural frequency of the substrate transfer device, and/or one or more harmonic frequencies of the substrate transfer device. The transfer device data 316 may further indicate one or more critical frequencies corresponding to vibration of the substrate transfer device.

In some embodiments, the frequency peak tool 334 analyzes the vibration data 314 to determine whether vibration at the critical frequency (e.g., a vibration frequency of interest associated with the substrate transfer device) exceeds a threshold magnitude. In some examples, the frequency peak tool 334 can determine that vibration at a particular frequency in the vibration data exceeds a warning threshold and/or a critical threshold. The warning threshold may indicate that one or more mechanical components of the substrate transfer device have worn beyond an early segment of useful life. The critical threshold may indicate that the one or more mechanical components have worn beyond a middle segment of useful life. A data signal indicative of the vibration exceeds the threshold magnitude may be communicated by the vibration sensor assembly (e.g., via network 340) to the client device 320 and/or the manufacturing system 302. In some embodiments, a portion of the raw and/or filtered vibration data 314 corresponding to a vibration event that exceeded the threshold magnitude is communicated with and/or as a part of the data signal. For example, a portion of the time domain vibration data 314 having observable vibration larger in magnitude than the threshold magnitude (e.g., the warning threshold magnitude and/or the critical threshold magnitude) may be sent with the data signal indicating the vibration frequency peak exceeds the threshold magnitude.

Data store 350 can be a memory (e.g., random access memory), a drive (e.g., a hard drive, a flash drive), a database system, or another type of component or device capable of storing data. Data store 350 can include multiple storage components (e.g., multiple drives or multiple databases) that can span multiple computing devices (e.g., multiple server computers). The data store 350 can store vibration data 314 and/or transfer device data 316.

One or more portions of data store 350 can be configured to store data that is not accessible to a user of the manufacturing system. In some embodiments, all data stored at data store 350 can be inaccessible by the manufacturing system user. In other or similar embodiments, a portion of data stored at data store 350 is inaccessible by the user while another portion of data stored at data store 350 is accessible to the user. In some embodiments, inaccessible data stored at data store 350 is encrypted using an encryption mechanism that is unknown to the user (e.g., data is encrypted using a private encryption key). In other or similar embodiments, data store 350 can include multiple data stores where data that is inaccessible to the user is stored in a first data store and data that is accessible to the user is stored in a second data store.

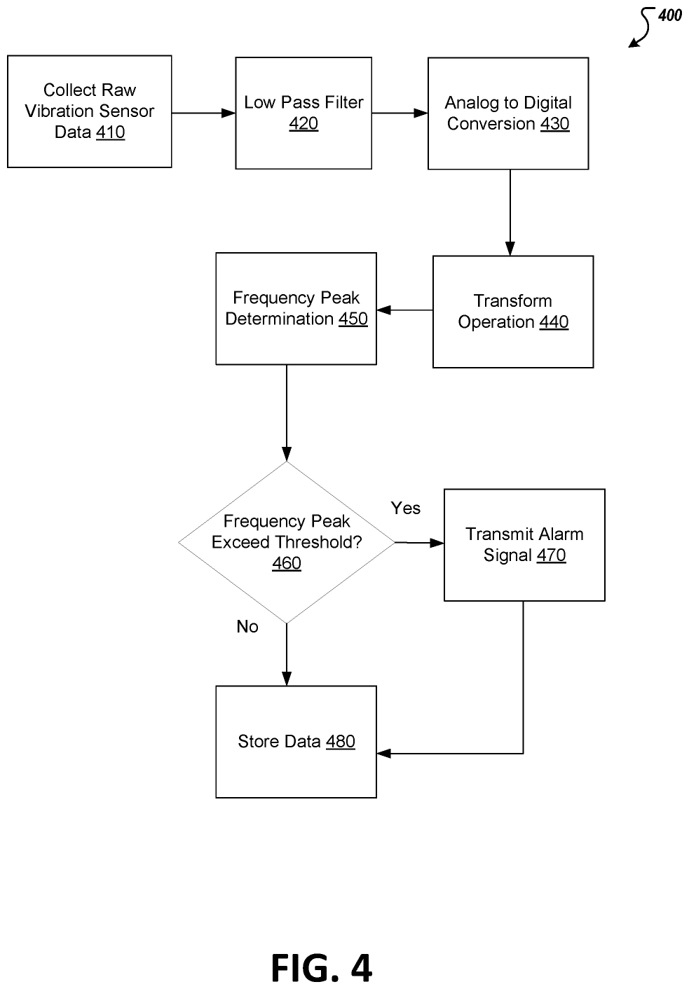

FIG. 4 is a flow chart of a method 400 for determining vibration in a substrate transfer device, according to aspects of the present disclosure. Method 400 is performed by processing logic that can include hardware (circuitry, dedicated logic, etc.), software (such as is run on a general purpose computer system or a dedicated machine), firmware, or some combination thereof. In one implementation, method 400 can be performed by a computer system, such as computer system architecture 300 of FIG. 3. In other or similar implementations, one or more operations of method 400 can be performed by one or more other machines not depicted in the figures.

For simplicity of explanation, method 400 is depicted and described as a series of operations. However, operations in accordance with this disclosure can occur in various orders and/or concurrently and with other operations not presented and described herein. Furthermore, not all illustrated operations may be performed to implement method 400 in accordance with the disclosed subject matter. In addition, those skilled in the art will understand and appreciate that method 400 could alternatively be represented as a series of interrelated states via a state diagram or events.

At block 410, processing logic collects raw vibration sensor data. In some embodiments, raw vibration data is output from a vibration sensor (e.g., an accelerometer configured to detect vibration). The vibration sensor may be coupled to a moveable member of a substrate transfer device (e.g., a wrist member of a substrate-handling robot). The raw vibration data may reflect the vibration of the substrate transfer device as the substrate transfer device moves and/or transfers substrates. The vibration may be induced by a failed or failing mechanical component such as a bearing, etc. The raw vibration data may indicate vibration due to the failed or failing mechanical component.

At block 420, the raw vibration sensor data is passed through a filter to filter noise out of the raw vibration sensor data. In some embodiments, the filter is a low-pass filter. For example, frequencies in the raw vibration sensor data above a predetermined cutoff frequency are filtered out of the data. Only frequencies below the cutoff frequency may be retained in the data. At block 430, the vibration sensor data is converted from an analog signal to a digital signal.

At block 440, processing logic transforms the digitally-represented vibration data. In some embodiments, the processing logic may apply a mathematical transformation operation to the digitally-represented vibration data. In some embodiments, processing logic transforms the vibration data from time domain to frequency domain using a Fourier transform (e.g., a Fast Fourier transform).

At block 450, at least one vibration frequency peak is determined in the frequency domain vibration data. The vibration frequency peak may correspond to a natural vibration frequency of the substrate transfer device or a harmonic vibration frequency of the substrate transfer device. In some embodiments, the vibration frequency peak may correspond to a wideband vibration frequency. (See FIG. 5 and associated description). The processing logic may examine certain frequency bands for peaks based on input associated with the type of substrate transfer device the vibration sensor is coupled to. For example, a technician may configure the processing logic to examine vibration frequencies that a particular type of substrate-handling robot tend to vibrate at (e.g., determined by experimentation). Further, in some embodiments, at block 450, processing logic may determine the magnitude(s) of the vibration frequency peak(s).

At block 460, processing logic determines whether the vibration frequency peak exceeds a predetermined threshold. In some embodiments, the threshold is based on input associated with the type of substrate transfer device the vibration sensor is coupled to, similar to as described with reference to block 450. The predetermined threshold may be a threshold magnitude. In some examples, the threshold magnitude corresponds to a warning level magnitude or to a critical level magnitude. The warning level magnitude may be associated with the vibration data indicating the substrate transfer device (e.g., a mechanical component of the substrate transfer device) has worn past an early segment of usable life. The substrate transfer device may then be in a mid-life segment of usable life, having a reduced lifespan compared to when in the early segment of usable life. The critical level magnitude may be associated with the vibration data indicating the substrate transfer device has worn past a mid-life segment of usable life. If the vibration frequency peak magnitude does not exceed the threshold, the method 400 proceeds to block 480 where the vibration data (e.g., time domain vibration data and/or frequency domain vibration data) is stored in a memory (e.g., data store 350 of FIG. 3). If the vibration frequency peak magnitude does exceed the threshold, the method 400 proceeds to block 470.

At block 470, processing logic causes an alarm signal to be transmitted. The alarm signal may be transmitted to a controller (e.g., system controller 128 of FIG. 1). In some embodiments, the alarm signal is a data signal indicative of the vibration frequency peak. For example, the data signal may indicate that the vibration frequency peak has a magnitude that exceeds the threshold magnitude (e.g., the warning level magnitude and/or the critical level magnitude). In some embodiments, the alarm signal indicates to the controller that maintenance is to be performed on the substrate transfer device. Maintenance can include lubrication, repair, and/or replacement of the substrate transfer device. In some embodiments, a portion of the time domain vibration sensor data is sent with the alarm signal. The portion of the time domain vibration sensor data may correspond to a vibration event that caused the vibration frequency peak to exceed the threshold magnitude.

FIG. 5 is a graphical representation of frequency domain vibration data 500 associated with vibration in a substrate transfer device, according to aspects of the present disclosure. Frequency domain vibration data 500 as shown in FIG. 5 may represent frequency domain vibration data converted from time domain vibration data converted via a mathematical transformation operation at block 440 of FIG. 4.

Vibration data 500 may illustrate various vibration amplitudes across certain frequency bands. For example, the vibration data 500 may indicate that vibration magnitude at the natural frequency 510a is less than both the critical vibration threshold 520a and the warning vibration threshold 522a. The vibration magnitude at the natural frequency 510a may be elevated, but is nonetheless at a safe level. As another example, the vibration data 500 may indicate that vibration magnitude at a first harmonic frequency 510b exceeds the warning threshold 522b but does not exceed the critical threshold 520b. This is indicated by the vibration peak at the first harmonic frequency 510b piercing the warning threshold 522b line. The vibration magnitude exceeding the warning threshold 522b may indicate that further observation of the substrate transfer device is to be conducted.

In another example, the data indicates that vibration at a third harmonic frequency 510d exceeds the critical threshold 520d. This may indicate a mechanical failure of a component of the substrate transfer device, such as a bearing, etc. Similarly, this may indicate that mechanical failure of the component is imminent and/or that the substrate transfer device or the component have entered the end-of-life segment. As a final example, the vibration magnitude along the wideband frequency 510e may indicate safe levels of vibration and/or that the substrate transfer device is in a safe state of operation.

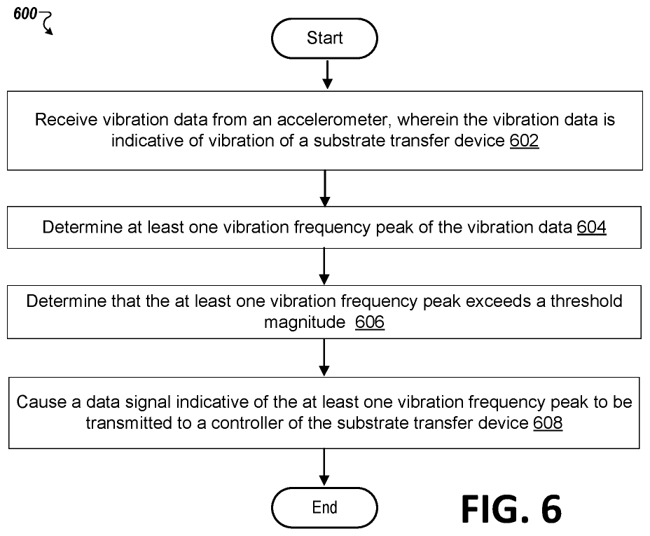

FIG. 6 is a flow chart of a method 600 for determining vibration in a substrate transfer device, according to aspects of the present disclosure. Method 600 is performed by a system that can include hardware (circuitry, dedicated logic, optical measuring tools as described herein, etc.), software (such as is run on a general purpose computer system or a dedicated machine), firmware, or some combination thereof. In one implementation, method 600 can be performed by a computer system, such as computer system architecture 300 of FIG. 3. In other or similar implementations, one or more operations of method 600 can be performed by one or more other machines not depicted in the figures.

For simplicity of explanation, method 600 is depicted and described as a series of operations. However, operations in accordance with this disclosure can occur in various orders and/or concurrently and with other operations not presented and described herein. Furthermore, not all illustrated operations may be performed to implement method 600 in accordance with the disclosed subject matter. In addition, those skilled in the art will understand and appreciate that method 600 could alternatively be represented as a series of interrelated states via a state diagram or events.

At block 602, processing logic receives vibration data from an accelerometer. The accelerometer may be part of a vibration sensor assembly coupled to a moveable member (e.g., a robot arm) of a substrate transfer device (e.g., a substrate-handling robot). The vibration data is indicative of vibration of the substrate transfer device. For example, the vibration data may indicate that a component of a substrate-handling robot, such as a wrist member, is vibrating during movement. The vibration may be caused by a worn component, such as a worn bearing. Vibration from a member of the substrate transfer device may be transferred through the other members of the substrate transfer device to the vibration sensor assembly. For example, vibration in an upper arm of a substrate-handling robot may be transferred through the upper arm to a forearm and to a wrist member, where the vibration sensor assembly can sense the vibration (e.g., via the accelerometer).

At block 604, processing logic determines a vibration frequency peak in the vibration data. In some embodiments, the processing logic determines more than one vibration frequency peak in the vibration data. The vibration frequency peak may be a magnitude of vibration at a particular frequency of vibration. In some examples, after the vibration data is converted from time domain to frequency domain, the processing logic can determine vibration peak magnitudes at discrete frequencies (see FIG. 5 and associated description).

At block 606, processing logic determines that the vibration frequency peak exceeds a threshold magnitude. In some embodiments, the threshold magnitude corresponds to a warning vibration level magnitude or to a critical vibration level magnitude. The warning vibration level magnitude may indicate that a mechanical component of the substrate transfer device (e.g., a bearing) is failing, that the substrate transfer device should be further monitored for vibration, and/or that a preventive maintenance operation (e.g., a lubrication operation, etc.) should be performed. The critical vibration level magnitude may indicate that a mechanical component of the substrate transfer device has failed, and/or that mechanical failure is imminent.

At block 608, processing logic causes a data signal indicative of the vibration frequency peak to be transmitted to a controller of the substrate transfer device. In some embodiments, the data signal indicates that the vibration has exceeded an acceptable level. For example, the data signal can indicate that vibration exceeds a warning magnitude threshold or a critical magnitude threshold. The data signal may indicate to the controller that maintenance should be performed. In some embodiments, the controller prepares a notification indicative of the vibration condition for display on a GUI.

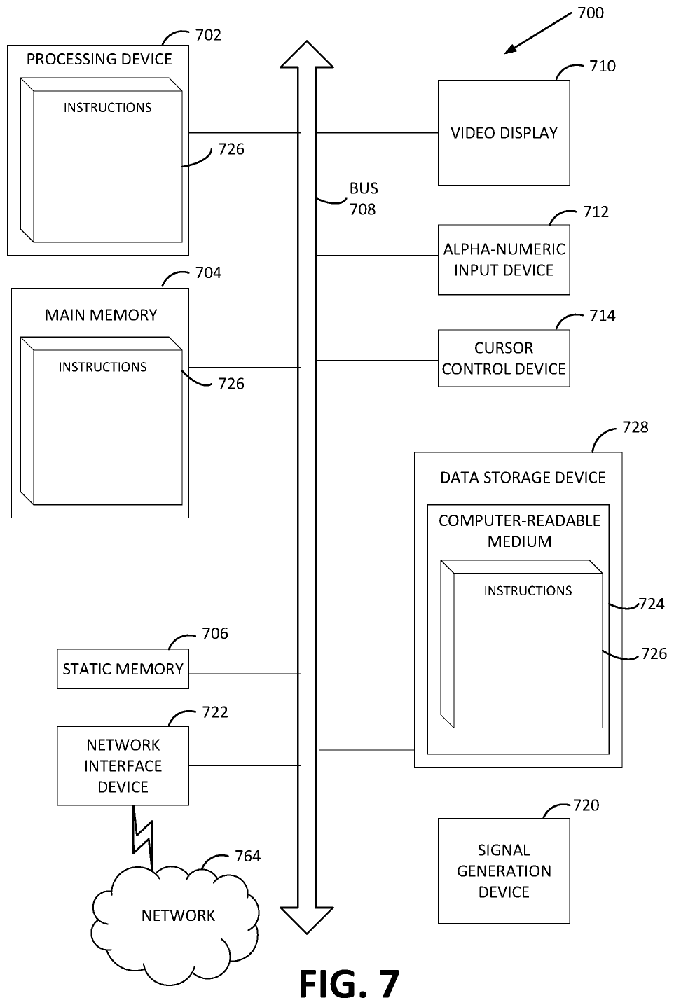

FIG. 7 depicts a diagrammatic representation of a machine in the example form of a computing device 700 within which a set of instructions, for causing the machine to perform any one or more of the methodologies discussed herein, can be executed. In alternative embodiments, the machine can be connected (e.g., networked) to other machines in a Local Area Network (LAN), an intranet, an extranet, or the Internet. The machine can operate in the capacity of a server or a client machine in a client-server network environment, or as a peer machine in a peer-to-peer (or distributed) network environment. The machine can be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The example computing device 700 includes a processing device 702, a main memory 704 (e.g., read-only memory (ROM), flash memory, dynamic random access memory (DRAM) such as synchronous DRAM (SDRAM), etc.), a static memory 706 (e.g., flash memory, static random access memory (SRAM), etc.), and a secondary memory (e.g., a data storage device 728), which communicate with each other via a bus 708.

Processing device 702 can represent one or more general-purpose processors such as a microprocessor, central processing unit, or the like. More particularly, the processing device 702 can be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. Processing device 702 can also be or include a system on a chip (SoC), programmable logic controller (PLC), or other type of processing device. Processing device 702 is configured to execute the processing logic for performing operations discussed herein.

The computing device 700 can further include a network interface device 722 for communicating with a network 764. The computing device 700 also can include a video display unit 710 (e.g., a liquid crystal display (LCD) or a cathode ray tube (CRT)), an alphanumeric input device 712 (e.g., a keyboard), a cursor control device 714 (e.g., a mouse), and a signal generation device 720 (e.g., a speaker).

The data storage device 728 can include a machine-readable storage medium (or more specifically a non-transitory machine-readable storage medium) 724 on which is stored one or more sets of instructions 726 embodying any one or more of the methodologies or functions described herein. A non-transitory storage medium refers to a storage medium other than a carrier wave. The instructions 726 can also reside, completely or at least partially, within the main memory 704 and/or within the processing device 702 during execution thereof by the computer device 700, the main memory 704 and the processing device 702 also constituting computer-readable storage media.

While the computer-readable storage medium 724 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of operations of each method can be altered so that certain operations can be performed in an inverse order so that certain operations can be performed, at least in part, concurrently with other operations. In another embodiment, instructions or sub-operations of distinct operations can be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a controller;
a substrate transfer device comprising one or more moveable members;
a vibration sensor assembly coupled to a first member of the one or more moveable members, the vibration sensor assembly comprising:
an accelerometer configured to detect vibration of the substrate transfer device; and
a processing device communicatively coupled to the accelerometer, wherein the processing device is to:
receive vibration data from the accelerometer, wherein the vibration data is indicative of the vibration of the substrate transfer device;
determine at least one vibration frequency peak of the vibration data, wherein the at least one vibration frequency peak corresponds to at least one critical frequency associated with the substrate transfer device;
determine that the at least one vibration frequency peak exceeds a threshold magnitude; and
responsive to determining that the at least one vibration frequency peak exceeds the threshold magnitude, cause a data signal indicative of the at least one vibration frequency peak to be transmitted to the controller.

2. The system of claim 1, wherein the controller is configured to:
receive the data signal indicative of the at least one vibration frequency peak exceeding the threshold magnitude; and
perform a corrective action based on the data signal.

3. The system of claim 2, wherein the corrective action comprises preparing for display on a graphical user interface (GUI) a notification of one or more of (i) the at least one vibration frequency peak exceeding the threshold magnitude or (ii) a preventive maintenance operation of the substrate transfer device corresponding to the critical frequency.

4. The system of claim 1, wherein the vibration sensor assembly further comprises:
a power source coupled to the accelerometer and the processing device, wherein the power source is configured to electrically power the accelerometer and the processing device.

5. The system of claim 1, wherein the threshold magnitude is associated with a segment of a usable lifetime of a component of the substrate transfer device.

6. The system of claim 1, wherein the substrate transfer device is disposed within a substrate transfer chamber, and wherein the data signal is periodically transmitted to the controller via wireless while a transfer port of the substrate transfer chamber is open.

7. The system of claim 1, wherein to determine the at least one vibration frequency peak of the vibration data, the processing device is to:
apply a mathematical transform operation to the vibration data to transform the vibration data from time domain to frequency domain,
wherein the processing device is further to cause a portion of the vibration data corresponding to a vibration event to the controller responsive to the vibration frequency peak exceeding the threshold magnitude to be transmitted.

8. The system of claim 1, wherein the substrate transfer device comprises a substrate-handling robot, and wherein the first member is a wrist member of the substrate-handling robot.

9. The system of claim 1, wherein the vibration sensor assembly further comprises an optical emitter configured to optically emit the data signal to an optical receiver communicatively coupled with the controller.

10. A vibration sensor assembly configured to couple to a moveable member of a substrate transfer device, the vibration sensor assembly comprising:
an accelerometer configured to detect vibration of the substrate transfer device;
a processing device communicatively coupled to the accelerometer, wherein the processing device is to:
receive vibration data from the accelerometer, wherein the vibration data is indicative of the vibration of the substrate transfer device;
determine at least one vibration frequency peak of the vibration data, wherein the at least one vibration frequency peak corresponds to at least one critical frequency associated with the substrate transfer device;
determine that the at least one vibration frequency peak exceeds a threshold magnitude; and
responsive to determining that the at least one vibration frequency peak exceeds the threshold magnitude, cause a data signal indicative of the at least one vibration frequency peak to be transmitted to a controller of the substrate transfer device.

11. The vibration sensor assembly of claim 10, further comprising:
a power source coupled to the accelerometer and the processing device, wherein the power source is configured to electrically power the accelerometer and the processing device.

12. The vibration sensor assembly of claim 10, wherein the vibration sensor assembly is configured to be disposed within a substrate transfer chamber, and wherein the processing device is configured to periodically transmit the data signal while a transfer port of the substrate transfer chamber is open.

13. The vibration sensor assembly of claim 10, wherein to determine the at least on vibration frequency peak of the vibration data, the processing device is to:
apply a mathematical transform operation to the vibration data to transform the vibration data from time domain to frequency domain,
wherein the processing device is further to cause a portion of the vibration data corresponding to a vibration event to the controller responsive to the vibration frequency peak exceeding the threshold magnitude to be transmitted.

14. The vibration sensor assembly of claim 10, wherein the moveable member of the substrate transfer device comprises a wrist member of a substrate-handling robot.

15. The vibration sensor assembly of claim 10, further comprising:
an optical emitter configured to optically emit the data signal to an optical receiver communicatively coupled with the controller.

16. A method comprising:
receiving vibration data from an accelerometer, wherein the vibration data is indicative of vibration of a substrate transfer device;
determining at least one vibration frequency peak of the vibration data, wherein the at least one vibration frequency peak corresponds to at least one critical frequency associated with the substrate transfer device;
determining that the at least one vibration frequency peak exceeds a threshold magnitude; and
responsive to determining that the at least one vibration frequency peak exceeds the threshold magnitude, causing a digital signal indicative of the at least one vibration frequency peak to be transmitted to a controller of the substrate transfer device.

17. The method of claim 16, wherein the threshold magnitude is associated with a segment of a lifetime of a component of the substrate transfer device.

18. The method of claim 16, wherein the data signal is periodically transmitted to the controller via wireless while a transfer port of a substrate transfer chamber is open.

19. The method of claim 16, wherein determining the at least one vibration frequency peak of the vibration data comprises:
applying a mathematical transform operation to the vibration data to transform the vibration data from time domain to frequency domain.

20. The method of claim 16, further comprising:
causing a portion of the vibration data corresponding to a vibration event to the controller responsive to the vibration frequency peak exceeding the threshold magnitude to be transmitted.
